(19) United States
(12) Patent Application Publication
(10) Pub. No.: US 2026/0253846 A1
(43) Pub. Date: Aug. 27, 2026

(54) PLASMA DEVICE

(71) Applicant: Beijing E-Town Semiconductor Technology Co., Ltd., Beijing (CN)

(72) Inventors: Changle GUAN, Beijing (CN); Qiang FAN, Beijing (CN)

(21) Appl. No.: 19/433,204

(22) Filed: Dec. 26, 2025

(30) Foreign Application Priority Data
Feb. 26, 2025 (CN) 202510217948.0

(51) Int. Cl. H01J 37/32; H10P 72/00

(52) U.S. Cl. CPC H01J 37/32522; H01J 37/321; H01J 2237/002; H01J 2237/334; H10P 72/0421

(57) ABSTRACT

Provided is a plasma device, relating to the field of semiconductor device technology. The plasma device includes: a chamber base; a medium cylinder sealed and matched with the chamber base; a coil component; and a cooling cylinder located between the medium cylinder and the coil component; the cooling cylinder is provided with air inlet holes for cooling gas to enter; the cooling cylinder has a first layer of cylinder wall and a second layer of cylinder wall, the first layer of cylinder wall is located on an inner side of the second layer of cylinder wall facing the medium cylinder, and a diversion channel is formed between the first layer of cylinder wall and the second layer of cylinder wall; the first layer of cylinder wall is provided with multiple air outlet holes, the air outlet holes and the air inlet holes are respectively connected to the diversion channel.

### CROSS-REFERENCE TO RELATED APPLICATIONS

The present application claims priority to Chinese Patent Application No. CN202510217948.0, filed with the China National Intellectual Property Administration on February 26, 2025, the disclosure of which is hereby incorporated herein by reference in its entirety.

### TECHNICAL FIELD

The present disclosure relates to the field of semiconductor device technology, in particular, to a plasma device.

### BACKGROUND

In related technologies, an ICP (Inductively Coupled Plasma Etcher) and a resist removing device are important process devices during a semiconductor chip manufacturing process, and remote plasma technology has been widely applied on these devices. A purpose of the remote plasma technology is to generate plasma in an area far away from a wafer, and process the wafer after the plasma reaches a wafer area. However, a process of generating the plasma generates higher temperature.

### SUMMARY

The present disclosure provides a plasma device which is capable of dissipating heat from a medium cylinder and reducing temperature of the medium cylinder.

The present disclosure provides a plasma device including: a chamber base, a top wall of the chamber base is provided with a first opening; a medium cylinder, which is located above the chamber base and is sealed and matched with the chamber base, to enable an internal space of the medium cylinder to connect to an internal space of the chamber base through the first opening; a coil component sheathed with outside of the medium cylinder; and a cooling cylinder which is located between the medium cylinder and the coil component and has a preset gap with the medium cylinder; the cooling cylinder is provided with air inlet holes for cooling gas to enter; the cooling cylinder has a first layer of cylinder wall and a second layer of cylinder wall, the first layer of cylinder wall is located on an inner side of the second layer of cylinder wall facing the medium cylinder, and a diversion channel is formed between the first layer of cylinder wall and the second layer of cylinder wall; the first layer of cylinder wall is provided with a plurality of air outlet holes, the air outlet holes and the air inlet holes are respectively connected to the diversion channel; a part of the air outlet holes is distributed at intervals along an axial direction of the cooling cylinder, and a part of the air outlet holes is distributed at intervals along a circumferential direction of the cooling cylinder; where under guidance of the diversion channel, the cooling gas entering from the air inlet holes is capable of flowing towards the plurality of air outlet holes, being discharged from the air outlet holes and then entering the preset gap to dissipate heat from the medium cylinder.

In some embodiments, the cooling cylinder includes a vertical segment and a bent segment, the vertical segment extends along the axial direction of the cooling cylinder, the vertical segment is connected to the bent segment, the bent segment extends along a direction away from the medium cylinder; the bent segment is provided with the air inlet holes, and at least a portion of the diversion channel is be located in the vertical segment.

In some embodiments, diameters of the air outlet holes gradually increase in a direction from bottom to top.

In some embodiments, distribution density of the air outlet holes gradually increases in the direction from bottom to top.

In some embodiments, diameters of the air outlet holes are less than or equal to 5 mm.

In some embodiments, the preset gap between the cooling cylinder and the medium cylinder is less than or equal to 5 mm.

In some embodiments, the cooling cylinder is provided with a plurality of long holes, a length direction of the long holes is parallel to the axial direction of the cooling cylinder; at least two of the long holes are distributed at intervals along the circumferential direction of the cooling cylinder; and a portion of the first layer of cylinder wall located between two adjacent ones of the long holes along the circumferential direction of the cooling cylinder is provided with the air outlet holes.

In some embodiments, the cooling cylinder is made of a metal material, or the cooling cylinder is made of a dielectric material.

In some embodiments, the cooling cylinder is be detachably connected to the chamber base.

In some embodiments, the plasma device further includes a cover plate covering an end of the medium cylinder facing away from the chamber base; and an air inlet apparatus, an air inlet pipeline of the air inlet apparatus is threaded through the cover plate.

The plasma device provided in the embodiments of the present disclosure enables the cooling gas entering from the air inlet holes of the cooling cylinder, being guided through the diversion channel to the air outlet holes and then being discharged to the medium cylinder to dissipate heat from the medium cylinder, reduce temperature of the medium cylinder, and improve or even avoid a problem of melting of the medium cylinder due to high temperature. Moreover, by reducing a temperature difference inside the medium cylinder, temperature uniformity of the medium cylinder is improved, and a problem of fracture of the medium cylinder due to excessive temperature difference is improved or even avoided.

It should be understood that contents described in this part is not intended to identify key or important features of the embodiments of the present disclosure, nor is it intended to limit the scope of the present disclosure. The other features of the present disclosure are made easy to be understood by the following description.

### BRIEF DESCRIPTION OF THE DRAWINGS

Accompanying drawings are provided for a better understanding of the present scheme and do not constitute a limitation of the present disclosure.

FIG. 1 is a schematic diagram of structure of a plasma device in an embodiment of the present disclosure.

FIG. 2 is a schematic diagram of a partial cross-segment of a plasma device in an embodiment of the present disclosure.

FIG. 3 is a schematic diagram of stereoscopic structure of a cooling cylinder in an embodiment of the present disclosure.

FIG. 4 is a schematic diagram of a cross-segment of a cooling cylinder in an embodiment of the present disclosure.

Explanation of reference numerals: 100-chamber base; 200-medium cylinder; 300-coil component; 400-cooling cylinder; 410-first layer of cylinder wall; 411-air inlet hole; 412-diversion channel; 413-air outlet hole; 420-second layer of cylinder wall; 400a-vertical segment; 400b-bent segment; 430-long hole; 440-sealing ring; 500-cover plate; 600-air intake apparatus; 700-vacuum pump; 800-wafer.

### DETAILED DESCRIPTION

Hereinafter, explanation of exemplary embodiments of the present disclosure will be made in conjunction with the accompanying drawings, which includes various details of the embodiments of the present disclosure to facilitate understanding and should be considered merely exemplary. Therefore, those having ordinary skill in the art should recognize that various changes and modifications may be made to the embodiments described herein without departing from the scope of the present disclosure. Similarly, for clarity and conciseness, descriptions of well-known functions and structures are omitted in the following descriptions.

In related technologies, a plasma device includes a chamber base, a medium cylinder and a coil component, a wafer area is provided in the chamber base, an ion excitation area is provided in the medium cylinder, and the coil component is positioned at outside of the medium cylinder. There is a certain distance between the icon excitation area and the wafer area, and in order to ensure concentration of excited stated components on a wafer surface, a higher power is used to excite and generate plasma. When the coil component is fed with energy, plasma concentration in an area corresponding to a coil in the coil component is the highest, and ions will bombard the medium cylinder, causing an increase in temperature of the medium cylinder and leading to a problem such as melting of the medium cylinder. Moreover, due to a spiral shape of the coil, it is not uniformly distributed relative to the medium cylinder, which can lead to poor temperature uniformity of the medium cylinder and cause a problem such as fracture of the medium cylinder.

In order to overcome the above problems, the present embodiment provides a plasma device by setting a cooling cylinder outside the medium cylinder, dissipating heat from the medium cylinder through cooling gas entering the cooling cylinder, reducing the temperature of the medium cylinder, and improving or even avoiding the problem of melting of the medium cylinder due to high temperature. Moreover, by reducing a temperature difference inside the medium cylinder, the temperature uniformity of the medium cylinder is improved, and the problem of fracture of the medium cylinder due to excessive temperature difference is improved or even avoided.

Structure, function, and implementation process of the plasma device provided in the present embodiment will be illustrated with reference to the accompanying drawings.

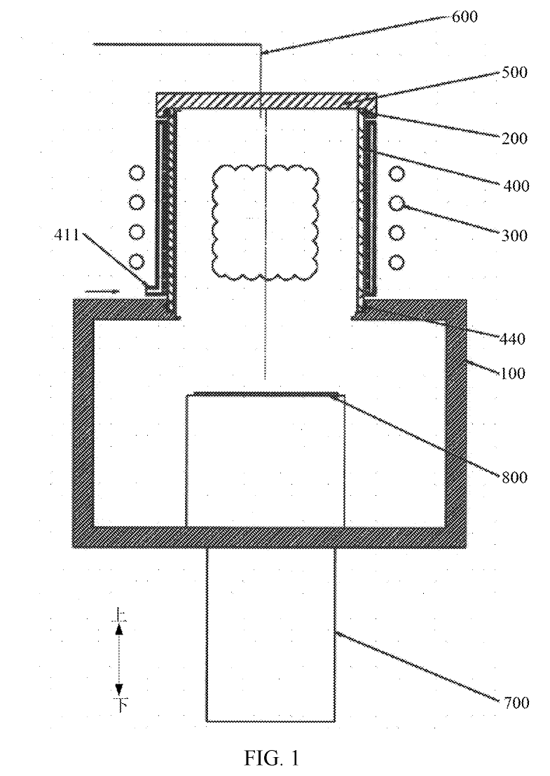

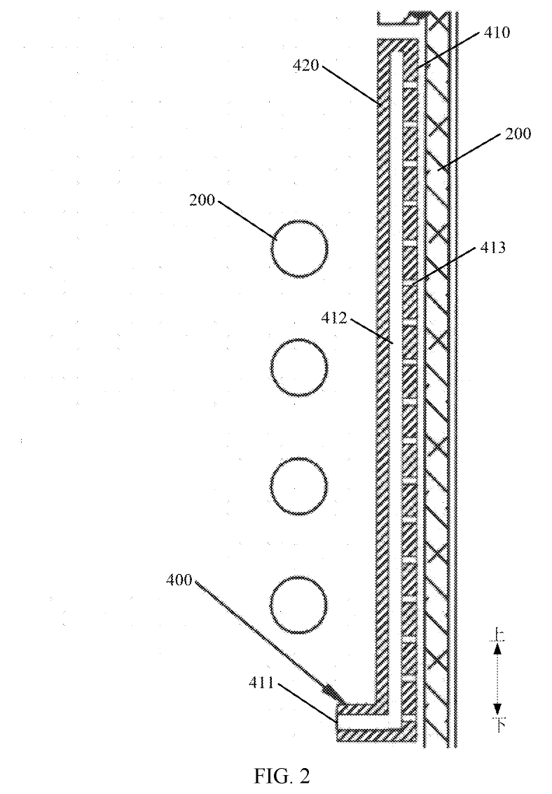

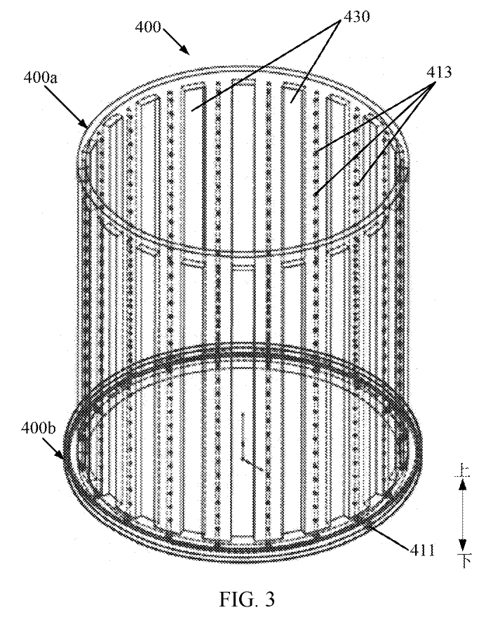

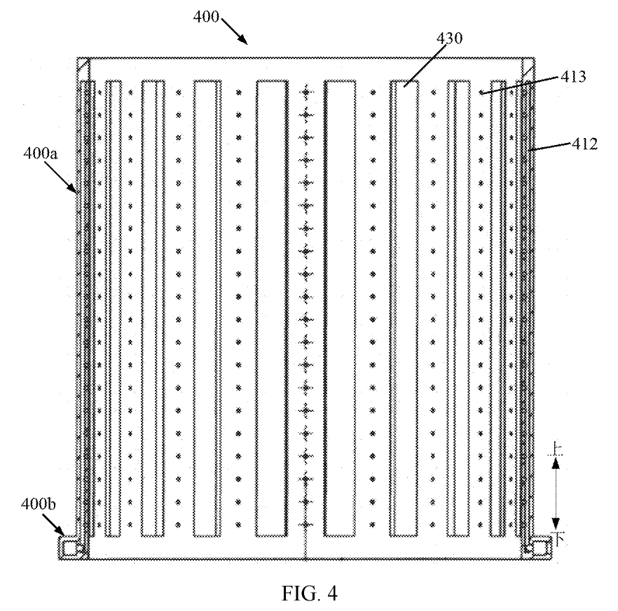

FIG. 1 is a schematic diagram of a cross-segment of a plasma device in an embodiment of the present disclosure (a vertical plane passing through a central axis of the plasma device is taken as the cross-segment); FIG. 2 is a schematic diagram of a partial cross-segment of a coil component, a cooling cylinder and a medium cylinder in an embodiment of the present disclosure; FIG. 3 is a schematic diagram of stereoscopic structure of a cooling cylinder in an embodiment of the present disclosure; FIG. 4 is a schematic diagram of a cross-segment of a cooling cylinder in an embodiment of the present disclosure (a vertical plane passing through a central axis of the plasma device is taken as the cross-segment).

Referring to FIGS. 1 to 4, the present embodiment provides a plasma device, which includes: a chamber base 100, a top wall of the chamber base 100 is provided with a first opening; a medium cylinder 200 which is located above the chamber base 100 and is sealed and matched with the chamber base 100, to enable an internal space of the chamber base 100 to connect to an internal space of the medium cylinder 200 through the first opening; a coil component 300 sheathed with outside of the medium cylinder 200; a cooling cylinder 400 which is located between the medium cylinder 200 and the coil component 300 and has a preset gap with the medium cylinder 200; the cooling cylinder 400 is provided with air inlet holes 411 for cooling gas to enter; the cooling cylinder 400 has a first layer of cylinder wall 410 and a second layer of cylinder wall 420, the first layer of cylinder wall 410 is located on an inner side of the second layer of cylinder wall 420 facing the medium cylinder 200, and a diversion channel 412 is formed between the first layer of cylinder wall 410 and the second layer of cylinder wall 420; the first layer of cylinder wall 410 is provided with a plurality of air outlet holes 413, the air outlet holes 413 and the air inlet holes 411 are respectively connected to the diversion channel 412; a part of the air outlet holes 413 is distributed at intervals along an axial direction of the cooling cylinder 400, and a part of the air outlet holes 413 is distributed at intervals along a circumferential direction of the cooling cylinder 400.

Under guidance of the diversion channel 412, the cooling gas entering from the air inlet holes 411 is capable of flowing towards the plurality of air outlet holes 413, being discharged from the air outlet holes 413 and then entering the preset gap to blow towards the medium cylinder 200 and dissipate heat from the medium cylinder 200.

The chamber base 100 is roughly cylindrical or prismatic in shape. The chamber base 100 has the internal space, and a shape of the internal space may be set according to actual needs, for example, the internal space of the chamber base 100 is roughly cylindrical or prismatic in shape. The internal space of the chamber base 100 is used to accommodate a wafer 800. Generally, a support apparatus for supporting the wafer 800 is provided in the internal space of the chamber base 100, the support apparatus may include at least one of a tray, a top pin, or an air floating block.

For ease of description, the present embodiment will take an axial direction of the chamber base 100 as a perpendicular direction (also known as a vertical direction) and taking a direction of the chamber base 100 facing the medium cylinder 200 as upward (also known as top) as examples for explanation.

The chamber base 100 has top and bottom ends spaced along its axis direction. The top wall of the chamber base 100 is provided with the first opening for gas to enter the internal space of the chamber base 100. The first opening may be a circular through-hole. In other examples, the first opening may also be polygonal, and a shape of the first opening may be set according to actual needs. Taking the chamber base 100 being cylindrical in shape as an example, a diameter of the first opening may be approximately half of an outer diameter of the chamber base 100.

The medium cylinder 200 is disposed above the chamber base 100, and may be a hollow column. The internal space of the medium cylinder 200 can provide space for generating ions. The medium cylinder 200 may be cylindrical in shape. In other examples, the medium cylinder 200 may also be prismatic in shape.

The medium cylinder 200 has the second opening, which corresponds to the first opening of the chamber base 100, so that the internal space of the medium cylinder 200 is connected to the internal space of the chamber base 100.

The medium cylinder 200 may be fixedly connected to and sealed and matched with a hole wall of the first opening. For example, the hole wall of the first opening may be stepped in shape, and the first opening includes a first hole segment and a second hole segment. The first hole segment is located above the second hole segment, and a diameter of the first hole segment is larger than that of the second hole segment. In this way, a support surface is formed at connection between the first hole segment and the second hole segment. The medium cylinder 200 is inserted into the first hole segment and supported on the support surface. In order to improve sealing reliability, a sealing ring 440 may be installed between an outer wall of the medium cylinder 200 and a hole wall of the first hole segment, or between a bottom surface of the medium cylinder 200 and the support surface.

The medium cylinder 200 also has a third opening located at a top of the medium cylinder 200. The top of the medium cylinder 200 may be covered with a cover plate 500, which is used to seal the third opening. In other examples, the cover plate 500 may also be integrated with the medium cylinder 200.

The plasma device may also include an air inlet apparatus 600, and an air inlet pipeline of the air inlet apparatus 600 is threaded through the cover plate 500 to supply gas into the medium cylinder 200.

The coil component 300 is sheathed with the outside of the medium cylinder 200, and is used to excite gas in the internal space of the medium cylinder 200 through radio frequency or microwave to form plasma when being supplied with energy. Power of the energy supplied to the coil component 300 may be set according to actual needs.

The coil component 300 may include a coil body and a coil mounting component, the coil mounting component is used to fixedly connect the coil body with other components of the plasma device. For example, the coil mounting component may fixedly connect the coil body to the chamber base 100. Structure of the coil mounting component may be set according to actual needs.

The cooling cylinder 400 is disposed between the coil component 300 and the medium cylinder 200. The cooling cylinder 400 is used to transport the cooling gas blown towards the medium cylinder 200, achieving cooling of the medium cylinder 200. The cooling cylinder 400 is closer to the medium cylinder 200 to ensure that gas discharged from the cooling cylinder 400 can blow towards the medium cylinder 200 as much as possible.

The cooling cylinder 400 may be a cylindrical structure sheathed with the outside of the medium cylinder 200. There is a certain gap between the medium cylinder 200 and the cooling cylinder 400, which allows the cooling gas discharged from the cooling cylinder 400 to flow in the gap, increasing a contact area between the cooling gas and the medium cylinder 200. A shape of the cooling cylinder 400 may be consistent with the shape of the medium cylinder 200. For example, when the medium cylinder 200 is cylindrical in shape, the cooling cylinder 400 may also be cylindrical in shape, and an inner diameter of the cooling cylinder 400 is slightly larger than an outer diameter of the medium cylinder 200.

The cooling cylinder 400 may have a double-layer structure. For example, the cooling cylinder 400 includes the first layer of cylinder wall 410 and the second layer of cylinder wall 420. The first layer of cylinder wall 410 is located on the inner side of the second layer of cylinder wall 420 facing the medium cylinder 200, that is, the first layer of cylinder wall 410 is closer to the medium cylinder 200. The diversion channel 412 is formed between the first layer cylinder wall 410 and the second layer cylinder wall 420. The first layer of cylinder wall 410 is provided with the plurality of air outlet holes 413. The cooling cylinder 400 is also provided with the air inlet holes 411. The air outlet holes 413 and the air inlet holes 411 are respectively connected to the diversion channel 412. In this way, the cooling gas enters from the air inlet holes 411, is guided through the diversion channel 412, and finally discharged from the air outlet holes 413 and blown towards the medium cylinder 200.

The part of the air outlet holes 413 is distributed at intervals along the axial direction of the cooling cylinder 400, and the part of the air outlet holes 413 is distributed at intervals along the circumferential direction of the cooling cylinder 400. In this way, a large number of air outlet holes 413 may be provided, and distribution of the air outlet holes 413 is relatively uniform, which is conducive to improving a cooling effect on the medium cylinder 200.

The cooling cylinder 400 is made of a metal material. At this point, the cooling cylinder 400 may also serve as a Faraday cylinder. Alternatively, the cooling cylinder 400 is made of a dielectric material. The dielectric material may include one of ceramic or quartz.

The cooling cylinder 400 may be detachably installed in the plasma device for easy maintenance or replacement of the cooling cylinder 400. For example, a bottom of the cooling cylinder 400 may be bolted or clamped to the chamber base 100 through an intermediate connector such as a mounting bracket or the like.

The plasma device provided in the present embodiment, through the above settings, enables the cooling gas entering from the air inlet holes 411 of the cooling cylinder 400, being guided through the diversion channel 412 to the air outlet holes 413 and then being discharged to the medium cylinder 200 to dissipate heat from the medium cylinder 200, reduce temperature of the medium cylinder 200, and improve or even avoid a problem of melting of the medium cylinder 200 due to high temperature. Moreover, by reducing a temperature difference inside the medium cylinder 200, temperature uniformity of the medium cylinder 200 is improved, and a problem of fracture of the medium cylinder 200 due to excessive temperature difference is improved or even avoided. Moreover, the present embodiment provides the air inlet holes 411, the diversion channel 412, and the air outlet holes 413 in the cooling cylinder 400, which will not affect a vacuum environment inside the medium cylinder 200 and can reduce an impact on feeding efficiency of the coil component 300.

In some embodiments, the cooling cylinder 400 includes a vertical segment 400a and a bent segment 400b. The vertical segment 400a extends along the axial direction of the cooling cylinder 400, and the bent segment 400b extends radially of the cooling cylinder 400. Alternatively, the bent segment 400b may be arranged perpendicular to the vertical segment 400a.

For example, in order to improve overall integrity of the cooling cylinder 400, the vertical segment 400a may be a hollow cylinder. A bottom end of the cylinder is connected to a structure extending in a direction away from a central axis of the cylinder, which forms the bent segment 400b. The bent segment 400b may be a ring-shaped structure. In other examples, the bent segment 400b may include at least one block structure.

The bent segment 400b is provided with the air inlet holes 411, and at least a portion of the diversion channel 412 may be located in the vertical segment 400a. For example, the air inlet holes 411 are provided through the bent segment 400b, and the diversion channel 412 is located in the vertical segment 400a; or, if the air inlet holes 411 is not provided through the bent segment 400b, a portion of the diversion channel 412 is located in the vertical segment 400a and another portion thereof is located in the bent segment 400b, so that the diversion channel 412 is connected to the air inlet holes 411.

In some examples, the bent segment 400b is connected to a bottom end of the vertical segment 400a. The bent segment 400b is provided with the air inlet holes 411 connected to a cooling gas source. For example, one end of the bent segment 400b facing away from the vertical segment 400a is provided with the air inlet holes 411, or in other words, an end surface of the first layer of cylinder wall 410 located on an end of the bent segment 400b facing away from the vertical segment 400a and an end surface of the second layer of cylinder wall 420 located on the end of the bent segment 400b facing away from the vertical segment 400a enclose the air inlet holes 411.

The cooling cylinder 400 may be provided with a plurality of columns of air outlet holes 413. By taking one straight line passing through the wall of the cooling cylinder 400 and passing through air outlet holes 413 and parallel to the axial direction of the cooling cylinder 400 as a reference line, a plurality of air outlet holes 413 that the reference line passes through may be a column of air outlet holes 413.

A portion of the bent segment 400b corresponding to at least two columns of air outlet holes 413 is provided with an air inlet hole 411. Alternatively, a portion of the bent segment 400b corresponding to each column of air outlet holes 413 is provided with the air inlet hole 411, which is beneficial for improving uniformity of the cooling effect. Alternatively, in order to simplify structure, the air inlet hole 411 is provided in a portion of the bent segment 400b corresponding to one of every two, three, or four air outlet holes 413. The number of the air inlet holes 411 may be set according to actual needs.

Alternatively, in order to improve an uneven cooling effect of the medium cylinder 200 caused by energy loss during flow of the cooling gas from bottom to top, diameters of the air outlet holes 413 gradually increase in a direction from bottom to top, thereby improving the uniformity of the cooling effect on the medium cylinder 200. During practical implementation, as an axial length of the cooling cylinder 400 increases, a ratio between a diameter of an upper air outlet hole 413 and a diameter of a lower air outlet hole 413 also increases. The ratio between the diameter of the upper air outlet hole 413 and the diameter of the lower air outlet hole 413 may be set according to actual needs.

Alternatively, in order to improve the uneven cooling effect of the medium cylinder 200 caused by energy loss during the flow of the cooling gas from bottom to top, distribution density of the air outlet holes 413 gradually increases in the direction from bottom to top, thereby improving the uniformity of the cooling effect on the medium cylinder 200. For example, a distance between two adjacent air outlet holes 413 along the axial direction gradually decreases from bottom to top. During practical implementation, as the axial length of the cooling cylinder 400 increases, a ratio between distribution density of air outlet holes 413 located in an upper area and distribution density of the air outlet holes 413 located in a lower area also increases. The ratio between the distribution density of the air outlet holes 413 located in the upper area and the distribution density of the air outlet holes 413 located in the lower area may be set according to actual needs.

In other examples, the vertical segment 400a has an upper part, a lower part, and a middle part connected between the upper and lower parts. The bent segment 400b may also be connected to the middle part or the upper part of the vertical segment 400a.

In some embodiments, the diameters of the air outlet holes 413 are less than or equal to 5 mm. For example, the diameters of the air outlet holes 413 may be 0.5 mm or 1.0 mm or 1.5 mm or 2.0 mm or 2.5 mm or 3.0 mm or 3.5 mm or 4.0 mm or 4.5 mm or 5.0 mm, or any value between any two of the above values. Through the above settings, the cooling cylinder 400 can be provided with a large number of air outlet holes 413, and also can ensure that speed or pressure of the cooling gas flowing out from the air outlet holes 413 reaches a preset value, thereby ensuring the cooling effect on the medium cylinder 200.

In some embodiments, the preset gap between the cooling cylinder 400 and the medium cylinder 200 is less than or equal to 5 mm. For example, the preset gap between the cooling cylinder 400 and the medium cylinder 200 may be 0.5 mm or 1.0 mm or 1.5 mm or 2.0 mm or 2.5 mm or 3.0 mm or 3.5 mm or 4.0 mm or 4.5 mm or 5.0 mm, or any value between any two of the above values. Through the above settings, it is possible to provide diffusion space for the cooling gas discharged from the air outlet holes 413, while avoiding the cooling effect of the medium cylinder 200 being affected by a large diffusion range of the cooling gas.

In some embodiments, in order to reduce its own weight of the cooling cylinder 400 and minimize an impact on energy feeding efficiency of the coil component 300, the cooling cylinder 400 is provided with a plurality of long holes 430, and a length direction of the long holes 430 is parallel to the axial direction of the cooling cylinder 400. The long holes 430 may be located at least in the vertical segment 400a of the cooling cylinder 400. For example, the long holes 430 are located in the vertical segment 400a, and for another example, most of the long holes 430 are located in the vertical segment 400a, and a small part of the long holes is located in the bent segment 400b. In addition, when the cooling cylinder 400 is made of a metal material such as aluminum alloy, the above settings can also achieve electrostatic shielding.

The long holes 430 may be set and penetrate along a thickness direction of the cooling cylinder 400. Alternatively, the long holes 430 may include a blind hole set on the first layer of cylinder wall 410, with a hole opening of this blind hole being located on an inner surface of the first layer of cylinder wall 410; and/or, a blind hole set on the second layer of cylinder wall 420, with a hole opening of this bind hole being located on an outer surface of the second layer of cylinder wall 420. It may be understood that when the long holes 430 are set and penetrate along the thickness direction of the cooling cylinder 400, the long holes are not connected to the diversion channel 412. The cooling cylinder 400 may be made by using an integrated molding processe such as 3D printing, injection molding, or stamping. Alternatively, the first layer of cylinder wall 410 and the second layer of cylinder wall 420 may be fixedly connected by using at least one of the following connection methods: bonding, clamping, screwing, welding, or the like.

Alternatively, at least two of the long holes 430 are distributed at intervals along the circumferential direction of the cooling cylinder 400. The air outlet holes 413 are provided between two adjacent ones of the long holes 430 along the circumferential direction of the cooling cylinder 400. The long holes 430 are spaced apart from the columns of air outlet holes 413. For example, one or more columns of air outlet holes 413 are provided between two adjacent long holes 430 along the circumferential direction of the cooling cylinder 400. For example, one or more long holes 430 are provided between two adjacent columns of air outlet holes 413 along the circumferential direction of the cooling cylinder 400.

In other examples, a long hole 430 may also be provided between two air outlet holes 413 spaced along the axial direction of the cooling cylinder 400. Alternatively, a long hole 430 may be provided between two air outlet holes 413 spaced along the circumferential direction of the cooling cylinder 400.

In some embodiments, the plasma device may further include a recycle apparatus for recycling the cooling gas located in the gap between the medium cylinder 200 and the cooling cylinder 400, which facilitates timely discharge of the cooling gas exchanged with the medium cylinder 200 from the gap between the medium cylinder 200 and the cooling cylinder 400.

For example, the recycle apparatus includes a recycling tray, which is provided with a central hole that may be used to cooperate with at least one of the cover plate 500, the medium cylinder 200, and the cooling cylinder 400. At least a portion of the recycling tray may be sheathed with the outside of the medium cylinder 200, or at least a portion of the recycling tray may be sheathed with outside of the cooling cylinder 400, or at least a portion of the recycling tray may be sheathed with outside of the cover plate 500. The recycling tray is provided with a recycling hole, which may be disposed extending along an inner circumference of the recycling tray, that is, an inner wall of the central hole, or there is a plurality of recycling holes evenly distributed along the inner circumference of the recycling tray. The recycling tray is provided with a recycling channel, which is connected to each recycling hole. The recycling tray may also be provided with an interface, which is connected to the recycling channel and may be connected to a recycling pipeline. The recycling pipeline may be connected to a suction component or a component that can accommodate gas. The cooling gas after heat exchange may enter into the recycling tray through the recycling hole and be guided through the recycling channel then be discharged into the recycling pipeline through the interface.

When the air inlet hole 411 of the cooling cylinder 400 is located at the bottom, the recycling tray may be placed near the top of the cooling cylinder 400. For example, there is a preset distance between a top end surface of the cooling cylinder 400 and a lower end surface of the cover plate 500, and at least a portion of the recycling tray may be located between a top end of the cooling cylinder 400 and a lower end of the cover plate 500, or the gap between the top end surface of the cooling cylinder 400 and the lower end surface of the cover plate 500 is connected to the recycling hole of the recycling tray, so that the cooling gas after heat exchange may enter into the recycling tray through the recycling hole.

Alternatively, a first valve may be installed in a gas source apparatus that provides the cooling gas; an inlet end of the recycling apparatus is provided with a second valve, for example, the second valve may be installed at the interface of the recycling tray; the first valve and the second valve are respectively connected in communication with a control apparatus of the plasma device. The control apparatus is used to control working status of the first valve and the second valve, such as controlling opening and closing and opening degree of the valves. For example, the control apparatus controls the first valve to open and controls the second valve to open every preset time period, timely discharging the cooling gas exchanged with the medium cylinder 200 from the gap between the medium cylinder 200 and the cooling cylinder 400. For example, after cooling of the medium cylinder 200 is completed, the control apparatus controls the first valve to close and controls the second valve to close after a preset time interval, ensuring that the cooling gas is discharged from the gap between the medium cylinder 200 and the cooling cylinder 400.

In some embodiments, a vacuum pump 700 is installed at the lower end of the chamber base 100, which is in communication with the control apparatus. The vacuum pump 700 is used to treat the internal space of the chamber base 100 into a vacuum environment.

It may be understood that other components and functions of the plasma device in the present embodiment are known to those skilled in the art, and will not be repeated here for reducing redundancy.

In the description of the present specification, it should be understood that directional or positional relationships indicated by terms “length”, “width”, “thickness”, “up”, “down”, “vertical”, “horizontal”, “top”, “bottom”, “inside”, “outside”, “axial”, “radial”, “circumferential” and the like are based on directional or positional relationships shown in the accompanying drawings, only for convenience of describing the present disclosure and simplifying the description, and do not indicate or imply that an apparatus or component referred to must have a specific orientation, be constructed and operated in a specific orientation, and therefore cannot be understood as a limitation on the present disclosure.

In addition, terms “first” and “second” are only used for a descriptive purpose and cannot be understood as indicating or implying relative importance or implying the number of technical features indicated. Therefore, features limited to “first” and “second” may explicitly or implicitly include one or more of these features. In the present disclosure, meaning of “a/the plurality of” refers to two or more, unless otherwise specifically limited.

In the present disclosure, unless otherwise specified and limited, terms “mount”, “connect”, “connection”, “fix” and the like should be broadly understood, for example, they may be fixed connections, detachable connections, or integrated; it may be mechanical connection, electrical connection, or communication; it may be directly connected or indirectly connected through an intermediate medium, and it may be a connection within two components or an interaction relationship between two components. For those having ordinary skill in the art, specific meanings of the above terms in the present disclosure may be understood according to a specific situation.

In the present disclosure, unless otherwise specified and limited, a first feature being “above” or “below” a second feature may include direct contact between the first and second features, or may include contact between the first and second features through another feature between them instead of the direct contact. Moreover, the first feature being “above”, “on”, or “over” the second feature includes the first feature being directly above and diagonally above the second feature, or simply indicating that the first feature is horizontally higher than the second feature. The first feature being “below”, “under” or “beneath” the second feature includes the first feature being directly below and diagonally below the second feature, or simply indicating that the first feature is horizontally lower than the second feature.

The above disclosure provides many different implementations or examples to achieve different structures of the present disclosure. In order to simplify the disclosure of the present disclosure, components and settings of specific examples are described in the preceding text. Of course, they are only examples and are not intended to limit the present disclosure. In addition, the present disclosure may repeat reference numbers and/or reference letters in different examples for a purpose of simplification and clarity, and does not in itself indicate a relationship between various embodiments and/or settings discussed.

The above is only specific implementations of the present disclosure, but the scope of protection of the present disclosure is not limited to this. Those having skill in the art can easily think of various changes or replacements within the technical scope disclosed in the present disclosure, which should be included in the protection scope of the present disclosure. Therefore, the s protection scope of the present disclosure should be based on the protection scope of the claims.

What is claimed is:

1. A plasma device, comprising:
a chamber base, a top wall of the chamber base is provided with a first opening;
a medium cylinder, which is located above the chamber base and is sealed and matched with the chamber base, to enable an internal space of the medium cylinder to connect to an internal space of the chamber base through the first opening;
a coil component sheathed with outside of the medium cylinder; and
a cooling cylinder which is located between the medium cylinder and the coil component and has a preset gap with the medium cylinder; the cooling cylinder is provided with air inlet holes for cooling gas to enter; the cooling cylinder has a first layer of cylinder wall and a second layer of cylinder wall, the first layer of cylinder wall is located on an inner side of the second layer of cylinder wall facing the medium cylinder, and a diversion channel is formed between the first layer of cylinder wall and the second layer of cylinder wall; the first layer of cylinder wall is provided with a plurality of air outlet holes, the air outlet holes and the air inlet holes are respectively connected to the diversion channel; a part of the air outlet holes is distributed at intervals along an axial direction of the cooling cylinder, and a part of the air outlet holes is distributed at intervals along a circumferential direction of the cooling cylinder;
wherein under guidance of the diversion channel, the cooling gas entering from the air inlet holes is capable of flowing towards the plurality of air outlet holes, being discharged from the air outlet holes and then entering the preset gap to dissipate heat from the medium cylinder.

2. The plasma device of claim 1, wherein the cooling cylinder comprises a vertical segment and a bent segment, the vertical segment extends along the axial direction of the cooling cylinder, the vertical segment is connected to the bent segment, the bent segment extends along a direction away from the medium cylinder; the bent segment is provided with the air inlet holes, and at least a portion of the diversion channel is be located in the vertical segment.

3. The plasma device of claim 2, wherein a bottom end of the vertical segment is connected to the bent segment.

4. The plasma device of claim 3, wherein diameters of the air outlet holes gradually increase in a direction from bottom to top.

5. The plasma device of claim 3, wherein distribution density of the air outlet holes gradually increases in the direction from bottom to top.

6. The plasma device of claim 1, wherein diameters of the air outlet holes are less than or equal to 5 mm; and/or
the preset gap between the cooling cylinder and the medium cylinder is less than or equal to 5 mm.

7. The plasma device of claim 1, wherein the cooling cylinder is provided with a plurality of long holes, a length direction of the long holes is parallel to the axial direction of the cooling cylinder;
at least two of the long holes are distributed at intervals along the circumferential direction of the cooling cylinder; and
a portion of the first layer of cylinder wall located between two adjacent ones of the long holes along the circumferential direction of the cooling cylinder is provided with the air outlet holes.

8. The plasma device of claim 1, wherein the cooling cylinder is made of a metal material, or the cooling cylinder is made of a dielectric material.

9. The plasma device of claim 1, wherein the cooling cylinder is be detachably connected to the chamber base.

10. The plasma device of claim 1, further comprising:
a cover plate covering an end of the medium cylinder facing away from the chamber base; and
an air inlet apparatus, an air inlet pipeline of the air inlet apparatus is threaded through the cover plate.
